(19) United States
(12) Patent Application Publication
(10) Pub. No.: US 2026/0072097 A1
(43) Pub. Date: Mar. 12, 2026

(54) SYSTEM ARCHITECTURE WITH FULL-POWER TEST OF AN INVERTER

(71) Applicant: EPC Power Corporation, Poway, CA (US)

(72) Inventors: David Michaud, Poway, CA (US); Christopher Lee, Poway, CA (US); William Giewont, Poway, CA (US)

(73) Assignee: EPC Power Corporation, Poway, CA (US)

(21) Appl. No.: 18/954,479

(22) Filed: Nov. 20, 2024

Related U.S. Application Data
(60) Provisional application No. 63/691,867, filed on Sep. 6, 2024.

(51) Int. Cl. G01R 31/42; H02J 3/38; H02J 13/00; H02M 7/44

(52) U.S. Cl. CPC G01R 31/42; H02J 3/38; H02J 13/12; H02M 7/44; H02J 2101/24

(57) ABSTRACT

A computing system can communicatively couple to a first power converter unit and a second power converter unit. The computing system can monitor power conversion performance of the first power converter unit, compare the power conversion performance to predetermined performance metrics, and determine an operational status of the first power converter unit based on the comparison.

### CROSS-REFERENCE TO RELATED PATENT APPLICATIONS

This application claims the benefit of and priority to U.S. Provisional Patent Application No.: 63/691,867, filed Sep. 6, 2024, the entirety of which is incorporated by reference herein.

### BACKGROUND

Renewable energy sites include solar panels and various electrical components including inverters to produce electrical power from sunlight.

### SUMMARY

At least one embodiment relates to a system including a solar assembly. The solar assembly can include one or more solar cells which convert sunlight into direct current (DC) power. The system can include a first power converter unit electrically coupled with the one or more solar cells. The first power converter unit can receive a first amount of DC power from the one or more solar cells. The first power converter unit can convert the first amount of DC power into a first amount of alternating current (AC) power. The first power converter unit can provide, responsive to conversion of the first amount of DC power into the first amount of AC power, the first amount of AC power to a second power converter unit electrically coupled with the first power converter unit. The second power converter unit can consume the first amount of AC power to act as an electric load for the first power converter unit. The second power converter unit can replicate, responsive to consumption of the first amount of AC power, a presence of an electric grid.

The system can include a computing system that communicates with the first power converter unit and the second power converter unit. The computing system can include one or more processing circuits that compare at least one of (1) the conversion of the first amount of DC power into the first amount of AC power or (2) the consumption of the first amount of AC power with one or more performance metrics. The one or more processing circuits can determine a status of the first power converter unit with respect to implementation of the first power converter unit at a renewable energy site.

At least one embodiment relates to a power converter unit. The power converter unit can include a first power stage. The first power stage can electrically couple with a direct current (DC) power line and an alternating current (AC) power line. The power conversion unit can include a second power stage. The second power stage can provide at least one of DC power or AC power to the first power stage. The power converter unit can include a controller. The controller can include one or more processing circuits that can control the second power stage to provide at least one of the DC power or the AC power to cause the first power stage to consume the DC power or the AC power.

At least one embodiment relates to a system. The system can be for testing power converter units. The system can include a first power converter unit. The first power converter unit can receive direct current (DC) power from a power source. The first power converter unit can convert the DC power into alternating current (AC) power. The first power converter unit can output the AC power. The system can include a second power converter unit. The second power converter unit can electrically couple to the first power converter unit. The second power converter unit can receive the AC power from the first power converter unit. The second power converter unit can consume the AC power to function as an electrical load. The second power converter unit can simulate operating characteristics of an electric grid. The system can include a computing system. The computing system can communicatively couple to the first power converter unit and the second power converter unit. The computing system can monitor power conversion performance of the first power converter unit. The computing system can compare the power conversion performance to predetermined performance metrics. The computing system can determine an operational status of the first power converter unit responsive to comparison of the power conversion performance to the predetermined performance metrics.

At least one embodiment relates to a method. The method can be for testing a power converter unit at a renewable energy site. The method can include receiving DC power from a renewable energy source at a first power converter unit. The method can include converting the DC power into AC power using the first power converter unit. The method can include providing the AC power to a second power converter unit that is electrically coupled to the first power converter unit. The method can include operating the second power converter unit to simulate electrical load characteristics of an electric grid by consuming the AC power. The method can include monitoring power conversion parameters of the first power converter unit during operation with the electrical load characteristics. The method can include determining whether the power conversion parameters satisfy predetermined performance requirements for connecting the first power converter unit to an actual electric grid.

At least one embodiment relates to a bi-directional power converter unit. The bi-directional power converter unit can include a first power stage. The first power stage can electrically couple to AC power lines and DC power lines. The first power stage can perform power conversion between AC and DC power. The bi-directional power converter unit can include a second power stage. The second power stage can electrically couple to the first power stage. The second power stage can selectively operate in a power consumption mode or a power generation mode. The bi-direction power converter unit can include a controller. The controller can control the first power stage and the second power stage to enable bi-directional power flow. The controller can operate the second power stage to consume power from the first power stage to simulate grid loading. The controller can monitor performance parameters during simulated grid loading operation.

### BRIEF DESCRIPTION OF THE DRAWINGS

FIG. 1 is a block diagram of a system to provide power to one or more components, according to some embodiments.

FIG. 2 is a schematic diagram of a system architecture to perform a power test of an inverter, according to some embodiments.

FIG. 3 is a block diagram of an inverter included in the system of FIG. 1, according to some embodiments.

FIG. 4 is a flow diagram of a process to perform a power test of an inverter, according to some embodiments.

The foregoing and other features of the present disclosure will become apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and make part of this disclosure.

Systems and methods to perform power tests of one or more power converter units are described herein. Power converter units (e.g., inverters, converters, rectifiers, etc.) are vital components for renewable energy sites (solar farms, wind farms, etc.) as the power converter units provide important functionality such as the conversion and/or the storage of energy produced at the renewable energy sites. For example, inverters may be coupled with solar panel arrays to convert direct current (DC) power, produced by the solar panel arrays, into alternating current (AC) power for distribution to power various devices.

Renewable energy sites are often located at reconfigured, modified, and/or altered locations. For example, a solar farm may be constructed in an open field that is without any infrastructure (e.g., water, gas, electric, etc.). The design and implementation of renewable energy sites consumes a significant amount of time (e.g., 6 months, 1 year, 2 years, etc.) prior to operation (e.g., generation of power) of the renewable energy sites. Once a renewable energy site is constructed and/or completed, the renewable energy site is subject to evaluation from a regulatory entity (e.g., department of energy, local authorities, government officials, etc.).

During the evaluation of the renewable energy site, power converter units are not able and/or authorized to start supplying power (e.g., convert DC power to AC power) to an electric and/or consuming power (AC power to DC power) from an electric grid. As a result, power converter units often do not undergo power test (e.g., test a conversion of power, test a consumption of power, etc.) prior to the completion of the evaluation of the renewable energy site. The lack of testing power converter units, during the construction and evaluation of renewable energy sites, can result in unexpected delays. For example, once a power converter unit is finally connected to an electric grid for testing, delays occur if the power converter unit malfunctions and/or experiences faults. Stated otherwise, the renewable energy site may be unable (e.g., delayed) to provide power to the electric grid.

The lack of testing power converter units, prior to the authorization of renewable energy sites, results from the inability to use the electric grid as a load or source for the power converter units. Stated otherwise, the power converter units are tested by using the electric grid as a load. Without the load (e.g., the electric grid), the power converter units are not able to experience loads indicative of how the power converter unit will ultimately be used (e.g., providing power to the electric grid).

Some technical solutions described herein include a system architecture and/or arrangement to perform a full-power test of a power converter unit with the use of the electric grid. Advantageously, power converter units may be tested prior to completion of the evaluation of the renewable energy site. For example, while a renewable energy site is undergoing an evaluation, the power converter units may also be tested (e.g., full-power test). The system architecture includes a power converter that includes two power stages that can be coupled on both the AC and DC terminals. Another embodiment is an inverter system including two or more converters (e.g., multiple converters). The first power converter unit (e.g., a first inverter) that is electrically coupled with a second power converter unit. The first power converter unit may refer to and/or include a tested unit (e.g., the power converter unit undergoing a full-power test). The second power converter unit may refer to and/or include the load unit (e.g., the power converter unit serving as an electric load).

The first power converter unit may receive DC power from one or more sources (e.g., solar panels, batteries, energy storage devices, etc.) and convert the DC power into AC power. To test the performance of the first power converter unit, the first power converter unit may be coupled with a component that consumes electrical energy, power, etc. (e.g., an electric load). For example, one or more output terminals of the first power converter unit may be coupled with one or more input terminals of the second power converter unit. The second power converter unit may consume power, provided by the first power converter unit, to serve as a load for the first power converter unit. Stated otherwise, the second power converter unit may draw and/or receive power from the first power converter unit. The system and/or arrangement described herein can be expanded for any number (e.g., 5, 10, 15, 20, 100, etc.) of power converter units to supply power and/or to serve as an electric load.

The power converter unit can include two power stages that can be electrically coupled with one or more terminals. For example, the two power stages can be electrically coupled with AC terminals and DC terminals. A first power stage can supply AC power to the second power stage. The second power stage can consume the AC power which causes the second power stage to produce DC power. Stated otherwise, the power converter unit can perform bi-directional power conversion (e.g., AC to DC and/or DC to AC) and/or bi-directional power flow.

The testing of the first power converter unit (e.g., the full-power test) may include monitoring an output (e.g., AC power) produced by the first power converter unit. For example, the first power converter unit may include a voltage rating and/or voltage amount (e.g., how much AC power the first power converter unit may produce). To continue this example, the output (e.g., AC power) of the first power converter unit may be compared to the voltage rating of the first power converter unit. Advantageously, the second power converter unit may draw and/or consume a given amount of power to cause the first power converter unit to produce power in accordance with the voltage rating. Stated otherwise, the second power converter unit may impose a demand, on the first power converter unit, to drive the first power converter unit to produce an amount of power that corresponds to the voltage rating.

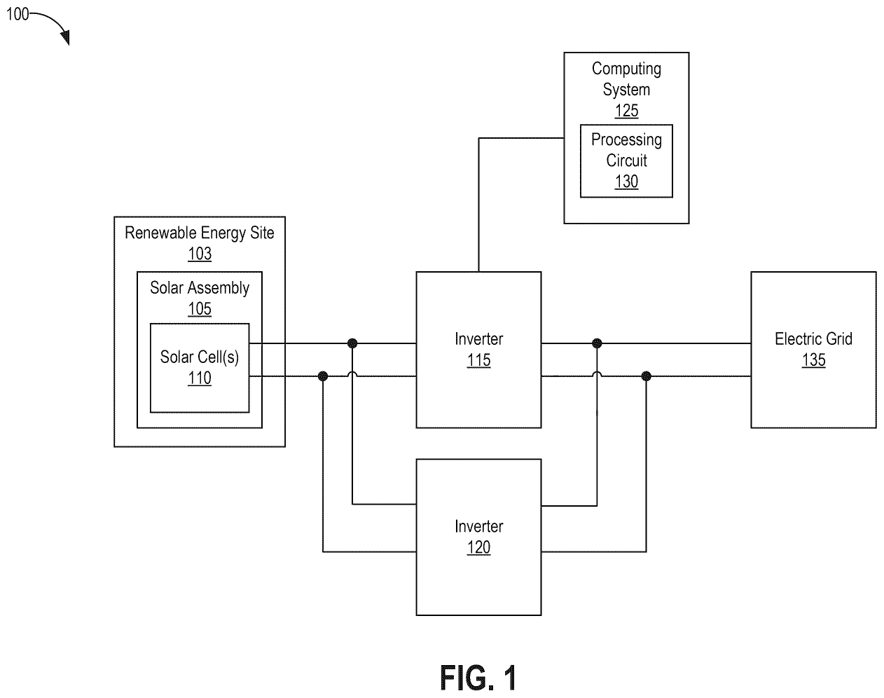

FIG. 1 is a block diagram of a system 100 to provide power to one or more components, according to some embodiments. For example, the various components of the system 100 may be utilized to provide electrical energy and/or power to one or more devices. In some embodiments, the system 100 may be modified and/or adjusted such that one or more components may be added, removed, substituted, altered, replaced, combined, separated, and/or otherwise changes. For example, a first component and a second component of the system 100 may be combined and/or otherwise joined. As another example, a single component of the system 100 may be replaced by multiple components.

As shown in FIG. 1, the system 100 includes a renewable energy site 103, an inverter 115, an inverter 120, a computing system 125, and an electric grid 135. In some embodiments, the various components of the system 100 may be electrical coupled and/or otherwise connected with one another such that a first component of the system 100 may provide electrical energy and/or power to one or more second components of the system 100. In some embodiments, at least one of the inverter 115 and/or the inverter 120 may represent multiple inverters. At least one power converter unit may refer to or include one or more solar inverters.

In some embodiments, the solar assembly 105 may include one or more solar panels and/or electrical devices, shown as solar cells 110, to facilitate the capture, receipt, and/or conversion of solar energy. For example, the solar cells 110 may include one or more photovoltaic (PV) cells that may convert sunlight into electrical power (e.g., energy, electricity, etc.). As another example, the solar cells 110 may produce DC power. In some embodiments, the solar assembly 105 may be provided as a discrete and/or separate component to that of the system 100. For example, the solar assembly 105 may be added to and/or provided to renewable energy site 103. Additionally and/or alternatively the solar assembly 105 may include one or more energy storage devices (e.g., batteries, power banks, etc.) to store DC power produced by the solar cells 110.

In some embodiments, the solar assembly 105 may be electrically coupled with one or more components and/or electrical circuitry of the system 100. For example, the solar assembly 105 (and/or the solar cells 110) may be electrically coupled with at least one of energy storage devices, power converter devices, and/or other electrical circuitry of the system 100. In some embodiments, the solar assembly 105 may provide and/or otherwise forward electrical energy, converted from sunlight and/or solar energy, to provide electrical energy to power one or more components and/or devices of the system 100. Stated otherwise, the solar assembly 105 may provide DC power from a renewable energy source.

In some embodiments, the inverter 115 and/or the inverter 120 may facilitate the transfer and/or conversion of electrical power. For example, the inverter 115 may receive DC power, from the solar assembly 105, and convert the DC power to AC power. As another example, the inverter 115 may include step-up and/or step-down electrical circuitry such that the DC power, from the solar assembly 105, may be increased and/or decreased to facilitate the transfer of DC to one or more components that operate on DC power.

In some embodiments, the inverter 115 may facilitate the transfer of electrical power by providing converted and/or adjusted electrical power (e.g., DC power converted to AC, DC to DC, AC to DC, etc.) to one or more components of the system 100. For example, the inverter 115 may be electrically coupled with the electric grid 135 such that the inverter 115 may provide AC power to the electric grid 135.

In some embodiments, the inverter 115 and/or the inverter 120 may be electrically coupled with the solar assembly 105. For example, the inverter 115 may be electrically coupled with the solar cells 110 via one or more wires and/or electrical coupling devices. The inverter 115 may receive DC power from the solar cells 110. For example, the inverter 145 may receive DC power as the solar cells 10 capture and/or otherwise convert sunlight into DC power. As another example, the inverter 115 may receive DC power from the solar cells 110 continuously and/or semi-continuous.

In some embodiments, the inverter 115 and/or the inverter 120 may convert and/or otherwise adjust electrical power. For example, the inverter 115 may convert the DC power, received from the solar cells 110, into AC power. As another example, the inverter 115 may adjust the DC power, received from the solar cells 110, by increasing and/or decreasing a DC voltage provided by the DC power. In some embodiments, the inverter 115 may provide electrical power to one or more components of the system 100. For example, the inverter 115 may provide AC power and/or DC power to one or more components of the computing system 125. As another example, the inverter 115 may serve and/or act as electric source for the electric grid 135.

In some embodiments, the computing system 125 may be electrically coupled with the inverter 115 and/or the inverter 120 such that the computing system 125 may monitor and/or evaluate operation and/or performance of the inverter 115 and/or the inverter 120. For example, the computing system 125 may monitor one or more outputs of the inverter 115. As another example, computing system 125 may evaluate a conversion rate of the inverter 120 (e.g., differences and/or ratios between DC power provided to the inverter 120 and AC power produced by the inverter 120). Additionally, or alternatively, the computing system 125 may monitor power conversion performance and/or power conversion parameters of the inverter 115.

In some embodiments, the computing system 125 may detect and/or diagnose a failed and/or poorly performing internal power stage or inverter. For example, the computing system 125 may compare a power conversion performance with one or more predetermined performance metrics (e.g., conversion rate, conversion percentage, power output, current levels, voltage amounts, etc.). The predetermined performance metrics may include at least one of power conversion efficiency ratings, maximum power output rating, voltage regulation specifications, and/or power quality parameters. As another example, the computing system 125 may detect one or more fault conditions with respect to the power conversion performance of the inverter 115. Stated otherwise, the computing system 125 may detect that the inverter 115 is not converting power in accordance with the predetermined performance metrics. In some embodiments, the computing system 125 may discontinue, disconnect, or otherwise isolate the inverter 115 responsive to detection of the fault condition. For example, the computing system 125 may electrically decouple the inverter 115 from the solar assembly 105. As another example, the computing system 125 may electrically decouple the inverter 115 from one or more DC power sources.

In some embodiments, the computing system 125 may determine an operational status of one or more power converter units. For example, the computing system 125 may determine an operational status of the inverter 115 based on a comparison between power conversion and predetermined metrics. The computing system 125 may compare a maximum power output, of the inverter 115, with one or more predetermined power output metrics. As another example, the computing system 125 may compare a power conversion rate, of the inverter 115, with one or more predetermined power conversion metrics.

In some embodiments, the computing system 125 may determine if one or more power conversion parameters satisfy predetermined performance requirements. For example, the computing system 125 may determine power conversion metrics, of the inverter 115, with one or more predetermined performance metrics. As another example, the computing system 125 may monitor, with respect to a power converter unit, at least one of input DC power levels, output AC power levels, conversion efficiency, and/or power quality metrics. In some embodiments, the computing system 125 may compare the power conversion parameters (e.g., measured parameters) to regulatory requirements. For example, a utility company or other entity may establish performance requirements of power converter units. In this example, the computing system 125 may compare the power conversion parameters of the inverter 115 with the power requirements. In some embodiments, the regulatory requirements may establish and/or dictate one or more standards in order for grid interconnection. Stated otherwise, the regulatory requirements may layout power conversion metrics in order to qualify for electric grid connection.

In some embodiments, the computing system 125 may store or otherwise maintain the power conversion parameters in a test log. For example, the computing system 125 may store the power conversion parameters as one or more data structures or entries within a digital file. As another example, the computing system 125 may store the power conversion parameters as indexes within the test log. The computing system 125 may generate one or more test reports based on the test log. For example, the computing system 125 may generate a test report which indicates an outcome (e.g., pass, fail, etc.) of a power conversion test that was performed on a power converter unit. As another example, the computing system 125 may generate a test report which lists or otherwise indicates one or more power conversion metrics and/or power conversion performance of the inverter 115. In some embodiments, the computing system 125 may certify a power converter unit for grid connection. For example, the computing system 125 may determine that the power conversion metrics, of the inverter 115, meet or satisfy one or more predetermined metrics for grid connection. As another example, the computing system 125 may determine that a power output, of the inverter 115, satisfies a regulatory requirement for grid interconnection.

As shown in FIG. 1, the computing system 125 includes a processing circuit 130. In some embodiments, the processing circuit 130 may include hardware, circuitry, firmware, software, etc. to facilitate and/or perform the various operations of the computing system 125. For example, the processing circuit 130 may include processors, coupled with memory, that execute one or more instructions stored in memory. As another example, memory may store executable code that, when executed by the one or more processors, causes the one or more processors to perform the operations of the computing system 125. In some embodiments, the computing system 125 may refer to and/or include one or more controllers.

In some embodiments, the computing system 125 may refer to and/or include at least one of a mobile device, a tablet, a computer, a desktop, a cloud computing device, a monitor, a laptop, remote servers, remote database, and/or an interactive display device. Additionally, and/or alternatively, the computing system 125 may include one or more network devices, output devices, and/or programable devices. For example, the computing system 125 may include one or more of transmitters, transceivers, receivers, antennas, network jacks, network interface cards, or other devices to facilitate communication (e.g., telecommunication, electronic communication, web-based communication, etc.) between one or more devices. As another example, the computing system 125 may include a human-machine interface (HMI), a monitor, a display device, a dashboard device, a keyboard, a mouse, a dial pad, or other devices to receive and/or provide information. In some embodiments, the computing system 125 may include wired and/or wireless connections. For example, the computing system 125 may be wired (e.g., connected) to the inverter 115 via an interface of the computing system 125. As another example, the computing system 125 may facilitate wireless communication between a controller of the inverter 115 and a controller of the inverter 120.

In some embodiments, the computing system 125 may include one or more communication interfaces that can transmit an operational status or operational status information to a remote monitoring system. For example, the computing system 125 may transmit, via the communication interfaces, performance metrics (e.g., operational status information) regarding one or more power converter units to a system that is remote from or isolated from the computing system 125. In some embodiments, the computing system 125 may receive, via the communication interface, control commands from an external test controller. For example, the computing system 125 may receive control commands to perform a power conversion test on the inverter 115. The control commands may include and/or indicate one or more metrics and/or parameters for which to test the inverter 115.

In some embodiments, the electrical coupling with and/or the providing of power to the electric grid 135 may depend on and/or rely on completion of an evaluation of the renewable energy site 103. For example, the inverter 115 may not be authorized to electrically couple with the electric grid 135 until the renewable energy site 103 received approval from a regulatory entity. As another example, the inverter 115 may be unauthorized to provide power (e.g., AC power, etc.) to the electric grid 135 until an evaluation of the renewable energy site 103 is completed. Accordingly, in some embodiments, the inverter 120 may serve as and/or provide an electric load to the inverter 115 such that the computing system 125 may evaluate power conversion and/or power production of the inverter 115.

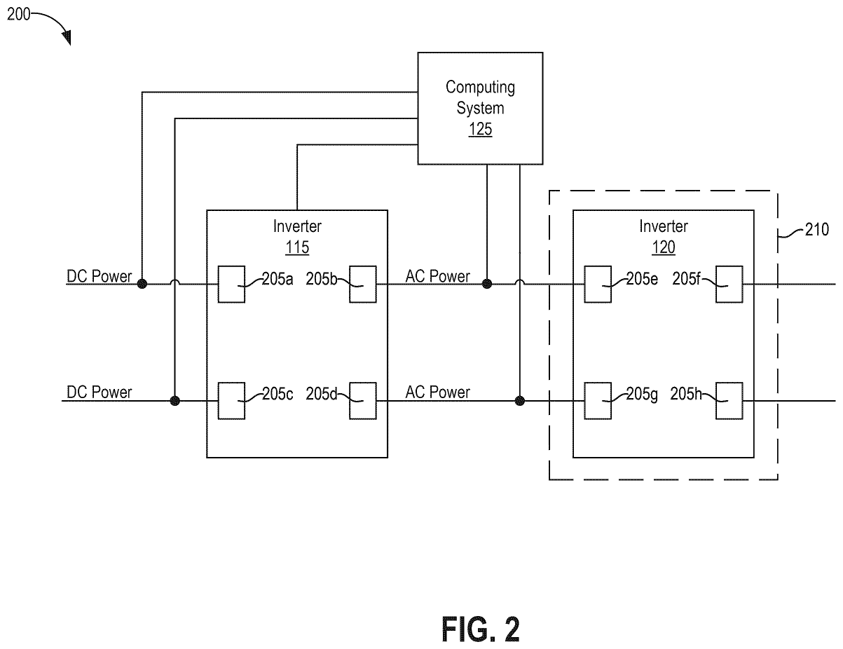

FIG. 2 depicts a schematic diagram of a system architecture 200 to perform a power test, according to some embodiments. For example, the system architecture 200 may be implemented to perform a power test on and/or with respect to the inverter 115. In some embodiments, the system architecture 200 may include one or more components of the system 100. For example, as shown in FIG. 2, the system architecture 200 includes the inverter 115, the inverter 120, and the computing system 125. In some embodiments, the computing system 125 may monitor and/or evaluate at least one of a conversion of power and/or a consumption of power. For example, the computing system 125 may monitor the inverter 115 with respect to the conversion of DC power into AC power. As another example, the computing system 125 may monitor a consumption of power by the inverter 120.

In some embodiments, the inverter 115 may include one or more terminals and/or ports, shown as terminals 205a, 205b, 205c, and 205d, to electrical couple one or more devices and/or components to the inverter 115. For example, the terminals 205a and 205c may electrically couple the solar assembly 105 with the inverter 115. In some embodiments, terminals 205b and 205d may electrically couple the inverter 115 with one or more loads. For example, as shown in FIG. 2, the terminals 205b and 205e are shown as electrically coupling the inverter 115 with the inverter 120. In some embodiments, the computing system 125 may monitor and/or detect signals and/or power transmitted to and/or from at least one of the terminals (e.g., terminals 205a, 205b, 205c, 205e, etc.) For example, as shown in FIG. 2, the computing system 125 may monitor an amount of DC power provided to the terminals 205a and 205c. As another example, the computing system 125 may monitor an amount of AC power outputted by the terminals 205b and 205d.

In some embodiments, the inverter 115 may receive power from one or more sources. For example, the inverter 115 may receive DC power from the solar cells 110. As another example, the inverter 115 may receive power from one or more energy storage devices and/or an auxiliary power supply. In some embodiments, the computing system 125 may facilitate a power test of the inverter 115 may monitoring power conversion of the inverter 115. For example, the computing system 125 may monitor given amounts of AC power output by the inverter 115.

In some embodiments, the inverter 120 may be electrically coupled with the inverter 115 such that inverter 120 may receive AC power from the inverter 120. For example, the terminals 205e and 205g of the inverter 120 may represent AC power input terminals (e.g., terminals configured to receive AC power). In some embodiments, the inverter 120 may consume AC power produced by the inverter 115. Stated otherwise, the inverter 120 may act as an electric load for the inverter 115 (e.g., a component that consumes power). As shown in FIG. 2, the inverter 120 may represent and/or act as electric load 210. For example, the electric load 210 (e.g., the inverter 120) may represent a demand that is placed on the inverter 115.

In some embodiments, the electric load 210 and/or presence of the electric load 210 may refer to and/or represent a simulation of operating characteristics of an electric grid (e.g., the electric grid 135). For example, the electric load 210 may consume or otherwise draw power from the inverter 115. As another example, the electric load 210 may replicate at least one of voltage and/or frequency characteristics of an electric grid (e.g., the electric grid 135). Stated otherwise, the electric load 210 may simulate electric load characteristics of an electric grid by consuming AC power produced by the inverter 115.

In some embodiments, the computing system 125 may adjust or otherwise change one or more power consumption levels of the inverter 120 to test the inverter 115 under one or more simulated grid loading conditions and/or grid load operation. For example, the computing system 125 may adjust how much power the electric load 210 demands or consumes, from the inverter 115, to simulate different load conditions.

In some embodiments, the inverter 120 may replicate a presence of an electric grid (e.g., grid forming). For example, the inverter 120 may impose a demand, on the inverter 115, similar to and/or indicative of a demand placed on the inverter 115 by the electric grid 135. In some embodiments, the inverter 120 may replicate the presence of the electric grid by serving and/or acting as the electric load 210. For example, the presence of the inverter 120 may cause the inverter 115 to convert DC power, from the solar cells 110, into AC power. As another example, the inverter 120 may consume and/or draw a given amount of power to evaluate a performance of the inverter 115.

In some embodiments, the computing system 125 may detect a presence of power at one or more terminals. For example, the computing system 125 may detect a presence of DC power at the terminal 205a. As another example, the computing system 125 may detect a presence of DC power at one or more voltage buses. In some embodiments, the computing system 125 may initiate one or more power conversion tests or power conversion testing in response to detecting DC power. For example, the computing system 125 may initiate a power conversion test, on the inverter 115, responsive to detecting DC power at one or more input terminals of the inverter 115.

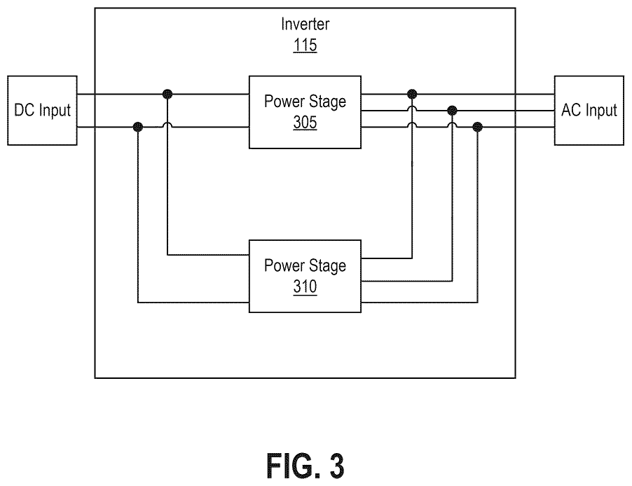

FIG. 3 depicts a block diagram of the inverter 115, according to some embodiments. As shown in FIG. 3, the inverter 115 includes a power stage 305 and a power stage 310. The power stage 305 and the power stage 310 may refer to and/or include a first power stage and a second power stage. The power stage 305 and the power stage 310 can be electrically coupled with one or more terminals and/or inputs to receive and/or provide power. For example, as shown in FIG. 3, the power stage 305 and the power stage 310 are shown electrically coupled with a DC input and an AC input. In some embodiments, the inverter 115 may include protection circuitry (e.g., relays, switches, fuses, etc.) that may prevent power backfeed to the DC input. For example, the inverter 115 may include circuitry that can prevent voltage from being returned, from the inverter 115, to the DC input. As another example, the inverter 115 may include circuitry that can isolate and/or disconnect the inverter 115 from the DC input.

In some embodiments, by applying AC power and/or DC power to a corresponding input (e.g., the DC input, AC input, etc.), a converter control unit of the inverter 115 (e.g., the computing system 125) can control at least one of the power stages to produce voltage (e.g., grid forming) and control the other power stage to consume power (e.g., grid follow). Additionally, the converter control unit can control bi-directional power distribution between the power stage 305 and the power stage 310. For example, when a DC source (e.g., the solar cells 110, batteries, etc.) provide DC power, via the DC input, the converter control unit can cause at least one of the power stage 305 or the power stage 310 to consume the DC power and then produce AC power. In some embodiments, the converter control unit may cause at least one of the power stage 305 or the power stage 310 to operate in a power consumption mode (e.g., consume power from a source) and/or a power generation source (e.g., generate and/or convert power). The converter control unit may synchronize and/or align power conversion operation between the power stage 305 and the power stage 310. For example, the converter control unit can synchronize the power stage 305 and the power stage 310 such that the power stage 305 produces power with the power stage 310 operating in a power consumption mode. As another example, the converter control unit can control the power stage 305 and the power stage 310 in unison.

In some embodiments, the computing system 125 may include memory and/or one or more memory devices that can store predetermined grid simulation parameters. For example, the computing system 125 may include one or more SSD cards that store information regarding grid simulation parameters. The grid simulation parameters may refer to and/or include power conversion metrics, power conversion parameters, and/or other possible metrics associated with connection to an electric grid. For example, the grid simulation parameters may identify an amount of power to provide to the electric grid. As another example, the grid simulation parameters may define one or power current values for which electric power may have when being provided to the electric grid. In some embodiments, the computing system 125 may control at least one power stage (e.g., the power stage 305, the power stage 310, etc.) according to the grid simulation parameters. For example, the computing system 125 may cause the power stage 305 to output an amount of power that conforms to and/or satisfies the grid simulation parameters.

In some embodiments, the computing system 125 may monitor one or more power quality parameters. For example, the computing system 125 may monitor power quality parameters, of a power stage, while the power stage is operating in a power consumption mode. The power quality parameters may refer to and/or include at least one of an amount of power being consumed by the power stage, an amount of current being received by the power stage, or an amount of voltage present at the power stage. In some embodiments, the computing system 125 may adjust one or more power consumption levels. For example, the computing system 125 may adjust one or more characteristics and/or operational setpoints of a power stage such that a power consumption level by the power stage is adjusted.

In some embodiments, the inverter 115 can produce voltage which then serves as a supply to test a performance of the inverter 120. For example, the inverter 115 can output DC voltage, which is then supplied to the inverter 120, to cause the inverter 120 to produce AC power. As another example, the inverter 115 can provide bi-directional flow between one or more sources and the inverter 120 such that the power, from the one or more sources, can be directed to the inverter 120 to test a performance of the inverter 120. Stated otherwise, the inverter 115 can operate in a power generation mode such that power is provided to the inverter 120.

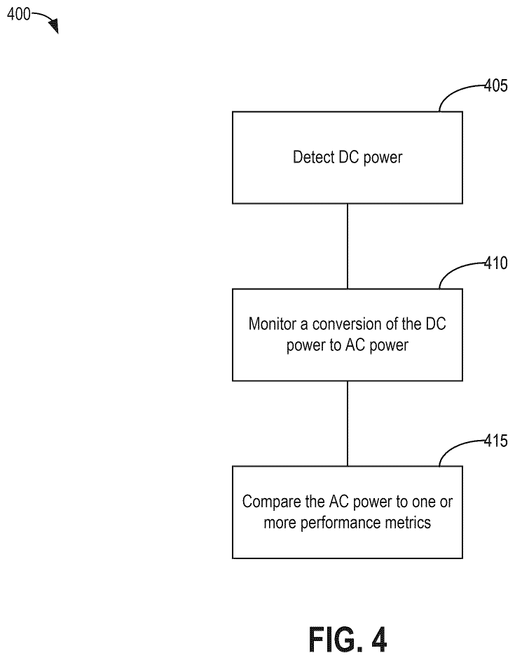

FIG. 4 depicts a flow diagram of a process 400 to perform a power test of an inverter, according to some embodiments. In some embodiments, at least one system, component, and/or device described herein may perform the process 400 and/or one or more steps thereof. For example, one or more components of the system architecture 200 may be implemented to perform the process 400. In some embodiments, the process 400 and/or one or more steps thereof may be modified and/or changed such that one or more steps may be skipped, omitted, repeated, separated, combined, replicated, and/or otherwise altered. For example, a given step of the process 400 may be performed more than once. As another example, a first given step and a second given step of the process 400 may be combined into a single step.

In some embodiments, at step 405, DC power may be detected. For example, the computing system 125 may detect DC power at the terminals 205a, 205c, 205f, and 205h. As another example, the computing system 125 may detect DC power on an input voltage bus of the inverter 120. In some embodiments, the computing system 125 may detect the DC power by monitoring a voltage level across one or more lines electrically coupled with the inverter 115. For example, the computing system 125 may detect the DC power by monitoring voltage across lines that couple the solar cells 110 with the inverter 115 and the inverter 120.

In some embodiments, at step 410, a conversion of DC power to AC power may be monitored. For example, the computing system 125 may monitor a conversion of power by the inverter 115. As another example, the computing system 125 may monitor an amount of AC power present at and/or on the terminals 205b and 205d. Stated otherwise, the computing system 125 may monitor how much AC power is output by the inverter 115 and consumed by the inverter 120. Additionally and/or alternatively, if AC voltage is present at the terminals of the inverter 115, the inverter 115 may convert AC power to DC power and the inverter 120 may consume the DC power to produce AC power.

In some embodiments, at step 415, the AC power may be compared to one or more performance metrics. For example, the computing system 125 may compare amounts of AC power, produced and/or output by the inverter 115, with one or more ratings and/or values associated with the inverter 115. In some embodiments, the ratings and/or values may include at least one voltage ratings, wattage ratings, power capacity, and/or conversion efficiency. For example, the inverter 115 may include a given wattage rating (e.g., how much power the inverter 115 may produce and/or output). To continue this example, the computing system 125 may compare the outputs of the inverter 115 (e.g., amount of AC power output at the terminals 205b and 205d) with the wattage rating.

In some embodiments, the computing system 125 may modify and/or otherwise control the inverter 120 to adjust one or more parameters of the inverter 120. For example, the computing system 125 may control operation of one or more devices of the inverter 120 to adjust an amount of power drawn by the inverter 120. Stated otherwise, the computing system 125 may control the inverter 120 to control the demand (e.g., the electric load 210) placed on the inverter 115 by the inverter 120. As another example, the computing system 125 may adjust operating parameters (e.g., power draw, electrical consumption, voltage draw, etc.) of the inverter 120 such that one or more operating characteristics of the inverter 120 and/or the electric load 210 are varied. In some embodiments, the computing system 125 may control the demand placed on the inverter 115 to perform a power test on the inverter 115. For example, the computing system 125 may adjust the electric load 210 such that the inverter 115 varying demands are placed on the inverter 115 to monitor performance (e.g., power conversion) of the inverter 115 at various electric loads.

In some embodiments, the computing system 125 may determine one or more statuses. For example, the computing system 125 may determine a status of the inverter 115. As another example, the computing system 125 may determine a status of the system 100. In some embodiments, the computing system 125 may determine the status of the inverter 115 responsive to comparing the AC power to the performance metrics in step 415. For example, the computing system 125 may determine that the inverter 115 is performing in accordance with a wattage rating based on an amount of AC power output by the inverter 115. As another example, the computing system 125 may determine that the inverter 115 is functioning properly based on the inverter 115 providing AC power to the inverter 120 while the inverter 120 is imposing a demand (e.g., electric load) on the inverter 115 that conforms to demands placed by the electric grid 135.

### Configuration of Exemplary Embodiments

In an illustrative embodiment, any of the operations described herein can be implemented at least in part as computer-readable instructions stored on a computer-readable memory. Upon execution of the computer-readable instructions by a processor, the computer-readable instructions can cause a node to perform the operations.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality, and any two components capable of being so associated can also be viewed as being “operably couplable,” to each other to achieve the desired functionality. Specific examples of operably couplable include but are not limited to physically mateable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.” Further, unless otherwise noted, the use of the words “approximate,” “about,” “around,” “substantially,” etc., mean plus or minus ten percent.

The foregoing description of illustrative embodiments has been presented for purposes of illustration and of description. It is not intended to be exhaustive or limiting with respect to the precise form disclosed, and modifications and variations are possible in light of the above teachings or may be acquired from practice of the disclosed embodiments. It is intended that the scope of the invention be defined by the claims appended hereto and their equivalents.

What is claimed:

1. A system for testing power converter units, comprising:
a first power converter unit configured to:
receive direct current (DC) power from a power source;
convert the DC power into alternating current (AC) power; and
output the AC power;
a second power converter unit electrically coupled to the first power converter unit and configured to:
receive the AC power from the first power converter unit;
consume the AC power to function as an electrical load; and
simulate operating characteristics of an electric grid; and
a computing system communicatively coupled to the first power converter unit and the second power converter unit, and the computing system configured to:
monitor power conversion performance of the first power converter unit;
compare the power conversion performance to predetermined performance metrics; and
determine an operational status of the first power converter unit responsive to comparison of the power conversion performance to the predetermined performance metrics.

2. The system of claim 1, wherein the computing system is further configured to:
detect presence of DC power at input terminals of the first power converter unit; and
initiate power conversion testing in response to detecting the DC power.

3. The system of claim 1, wherein the predetermined performance metrics include at least one of:
power conversion efficiency ratings;
maximum power output ratings;
voltage regulation specifications; or
power quality parameters.

4. The system of claim 1, wherein the computing system is further configured to:
adjust operating parameters of the second power converter unit to vary the operating characteristics.

5. The system of claim 1, wherein the power source comprises a solar array, and wherein the first power converter unit comprises a solar inverter.

6. The system of claim 1, further comprising:
a communication interface configured to transmit the operational status to a remote monitoring system.

7. The system of claim 1, wherein the second power converter unit is configured to:
replicate voltage and frequency characteristics of the electric grid.

8. A method of testing a power converter unit at a renewable energy site, comprising:
receiving DC power from a renewable energy source at a first power converter unit;
converting the DC power into AC power using the first power converter unit;
providing the AC power to a second power converter unit that is electrically coupled to the first power converter unit;
operating the second power converter unit to simulate electrical load characteristics of an electric grid by consuming the AC power;
monitoring power conversion parameters of the first power converter unit during operation with the electrical load characteristics; and
determining whether the power conversion parameters satisfy predetermined performance requirements for connecting the first power converter unit to an actual electric grid.

9. The method of claim 8, further comprising:
adjusting power consumption levels of the second power converter unit to test the first power converter unit under different simulated grid loading conditions.

10. The method of claim 8, wherein monitoring the power conversion parameters comprises:
measuring at least one of:
input DC power levels;
output AC power levels;
conversion efficiency; or
power quality metrics.

11. The method of claim 8, further comprising:
storing the power conversion parameters in a test log; and
generating a test report based on the test log.

12. The method of claim 8, further comprising:
detecting a fault condition during testing; and
automatically discontinuing power conversion testing in response to detecting the fault condition.

13. The method of claim 8, wherein determining whether the power conversion parameters satisfy requirements comprises:
comparing measured parameters to regulatory requirements for grid interconnection.

14. The method of claim 8, further comprising:
certifying the first power converter unit for grid connection responsive to determining that the power conversion parameters satisfy the predetermined performance requirements.

15. A bi-directional power converter unit, comprising:
a first power stage configured to:
electrically couple to AC and DC power lines; and
perform power conversion between AC and DC power;
a second power stage configured to:
electrically couple to the first power stage; and
selectively operate in a power consumption mode or a power generation mode; and
a controller configured to:
control the first power stage and the second power stage to enable bi-directional power flow;
operate the second power stage to consume power from the first power stage to simulate grid loading; and
monitor performance parameters during simulated grid loading operation.

16. The bi-directional power converter unit of claim 15, wherein the controller is further configured to:
monitor power quality parameters during power consumption operation; and
adjust power consumption levels based on the power quality parameters.

17. The bi-directional power converter unit of claim 15, further comprising:
protection circuitry configured to prevent power backfeed to input power sources.

18. The bi-directional power converter unit of claim 15, wherein the controller is further configured to:
synchronize power conversion operations between the first power stage and the second power stage.

19. The bi-directional power converter unit of claim 15, further comprising:
a communication interface configured to receive control commands from an external test controller.

20. The bi-directional power converter unit of claim 15, wherein the controller comprises:
memory storing predetermined grid simulation parameters; and
processing circuitry configured to control power stages according to the predetermined grid simulation parameters.
